(19) United States
(12) Patent Application Publication
(10) Pub. No.: US 2014/0196251 A1
(43) Pub. Date: Jul. 17, 2014

(54) SEMICONDUCTOR FABRICATING APPARATUS

(71) Applicant: UNITED MICROELECTRONICS CORP., Hsin-Chu City (TW)

(72) Inventors: YINGJIE XU, Singapore (SG); Chaw Che, Singapore (SG); Yu-Yang Chen, Singapore (SG); Liang-Yong Tan, Singapore (SG); HAI YUAN, Singapore (SG); XIANYU MENG, Singapore (SG)

(73) Assignee: UNITED MICROELECTRONICS CORP., Hsin-Chu City (TW)

(21) Appl. No.: 13/740,254

(22) Filed: Jan. 13, 2013

(51) Int. Cl. H01L 21/67

(52) U.S. Cl. CPC H01L 21/67005
USPC 15/406

(57) ABSTRACT

A semiconductor fabricating apparatus includes a reaction chamber, a first gas pipeline, and a second gas pipeline. The first gas pipeline includes a first cleaning gas pipeline for providing a first cleansing gas to the reaction chamber in a cleansing process, and a second cleansing gas pipeline for providing a second cleansing gas to the reaction chamber in the cleansing process. The first cleansing gas pipeline and the second cleansing gas pipeline are connected in parallel. The second gas pipeline provides a reactive gas to the reaction chamber in a fabricating process. The first gas pipeline and the second gas pipeline are connected in parallel.

### BACKGROUND OF THE INVENTION

1. Field of the Invention

The invention relates to a semiconductor fabricating apparatus, and more particularly, to a semiconductor fabricating apparatus capable of preventing contamination.

2. Description of the Prior Art

A semiconductor fabricating apparatus is a very delicate machine in which semiconductor fabricating process is performed. Conventional semiconductor fabricating apparatus exemplarily includes diffusion furnace for growing a layer or diffusing impurities at a high temperature, a plasma apparatus for chemical vapor deposition or etching, an apparatus for implanting, and an apparatus for depositing.

With the trend in semiconductor devices toward high function and high density, it is important to reduce contamination in such delicate apparatus because the contaminations generated in the process and remained in the apparatus may severely damage the semiconductor devices.

Therefore, it is necessary for the semiconductor fabricating apparatus to be cleaned for preventing contaminations.

### SUMMARY OF THE INVENTION

According to the claimed invention, a semiconductor fabricating apparatus is provided. The semiconductor fabricating apparatus includes a reaction chamber, a first gas pipeline, and a second gas pipeline. The first gas pipeline includes a first cleaning gas pipeline for providing a first cleansing gas to the reaction chamber in a cleansing process, and a second cleansing gas pipeline for providing a second cleansing gas to the reaction chamber in the cleansing process. The first cleansing gas pipeline and the second cleansing gas pipeline are connected in parallel. The second gas pipeline provides a reactive gas to the reaction chamber in a fabricating process. The first gas pipeline and the second gas pipeline are connected in parallel.

According to the semiconductor fabricating apparatus provided by the present invention, the first cleansing gas is introduced to clean the reaction chamber in the cleansing process. The first cleansing gas and any contamination generated in the cleansing process are driven out from the reaction chamber by the second cleansing gas. After the cleansing process which involves both of the first cleansing gas and the second cleansing gas, the reactive gas is introduced into the reaction chamber in the fabricating process. Since the contaminations and remnant gas are all removed from the reaction chamber, there will be no adverse impact rendered to the semiconductor fabricating process performed in the reaction chamber.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic drawings illustrating a semiconductor fabricating apparatus in different operation modes provided by a preferred embodiment of the present invention, wherein

FIG. 1 is a schematic drawing illustrating a semiconductor fabricating apparatus in a step of a cleansing process.

FIG. 2 is a schematic drawing illustrating a semiconductor fabricating apparatus in a step of a cleansing process subsequent to FIG. 1.

FIG. 3 is a schematic drawing illustrating a semiconductor fabricating apparatus in a step of a fabricating process.

### DETAILED DESCRIPTION

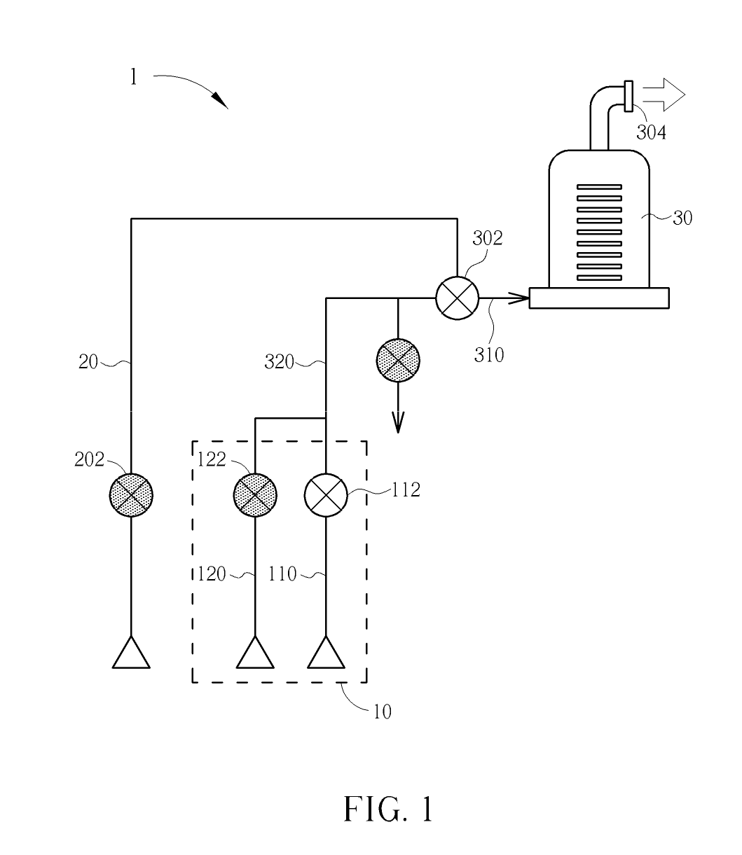

Please refer to FIGS. 1-3, which are schematic drawings illustrating a semiconductor fabricating apparatus in different operation modes provided by a preferred embodiment of the present invention. As shown in FIGS. 1-3, the preferred embodiment provides a semiconductor fabricating apparatus 1. The semiconductor fabricating apparatus 1 includes a first gas pipeline 10, a second gas pipeline 20, and a reaction chamber 30. The reaction chamber 30 is used to accommodate wafers undergo the semiconductor fabricating process, and a semiconductor fabricating process, such as a silicon nitride (SiN) material or a tetra-ethyl-ortho-silicate (TEOS) material deposition is performed in the reaction chamber 30. In the aforementioned semiconductor fabricating process, nitrogen (N₂) gas serves as a reactive gas. However, those skilled in the art would easily realize that the reactive gas can include gas other than N₂ according different requirements of the semiconductor fabricating processes. As shown in FIGS. 1-3, the reaction chamber 30 includes a gas outlet 304 for removing any unnecessary gas from the reaction chamber 30.

Please refer to FIGS. 1-3 again. The first gas pipeline 10 and the second gas pipeline 20 of the semiconductor fabricating apparatus 1 are connected in parallel. More important, the first gas pipeline 10 and the second gas pipeline 20 are connected to the reaction chamber 30 by a first connection pipeline 310. The first gas pipeline 10 further includes a first cleansing gas pipeline 110 and a second cleansing gas pipeline 120. It should be noted that the first cleansing gas pipeline 110 and the second cleansing gas pipeline 120 are connected in parallel. More important, the semiconductor fabricating apparatus 1 includes a second connection pipeline 320 connecting the first cleansing gas pipeline 110 and the second cleansing gas pipeline 120. In other words, the second gas pipeline 20 and the second connection pipeline 320 (connecting the first cleansing gas pipeline 110 and the second cleansing gas pipeline 120) are connected in parallel to the first connection pipeline 310 as shown in FIGS. 1-3. Furthermore, a first valve 112 is positioned at the first cleansing gas pipeline 110, a second valve 122 is positioned at the second cleansing gas pipeline 120, and a third valve 302 is positioned at a joint between the first gas pipeline 10 and the second gas pipeline 20. In other words, the third valve 302 is positioned at a joint of the second gas pipeline 20, the second connection pipeline 320, and the first connection pipeline 310. Additionally, a fourth valve 202 is positioned at the second gas pipeline 20 as shown in FIGS. 1-3. The first valve 112 serves as an open/close switch mechanism for the first cleansing gas pipeline 110, the second valve 122 serves as an open/close switch mechanism for the second cleansing gas pipeline 120, and the fourth valve 202 serves as an open/close switch mechanism for the second gas pipeline 20. Different from the first valve 112, the second valve 122 and the fourth valve 202, the third valve 302 is a triple action valve. Accordingly, the third valve 302 can be operated in any one of three positioned for obstructing and closing the second gas pipeline 20, the first connection pipeline 310, or the second connection pipeline 320.

Please still refer to FIGS. 1-3. The second gas pipeline 20 is used to provide the reactive gas, for example but not limited to, N₂ in a fabricating process according to the preferred embodiment. It is well-known that the reaction chamber 30 requires a cleansing process for preventing contamination, and therefore the first cleansing gas pipeline 110 and the second cleansing gas pipeline 120 are used to provide the cleansing gases in a cleansing process. It is noteworthy that the first cleansing gas pipeline 110 provides a first cleansing gas to the reaction chamber 30, the second cleansing gas pipeline 120 provides a second cleansing gas to the reaction chamber 30, and the second cleansing gas is different from the first cleansing gas. For example, the first cleansing gas includes hydrogen fluoride (HF) and the second cleansing gas includes N₂. It is found that the second cleansing gas and the reactive gas preferably include the same gas in accordance with the preferred embodiment, however those skilled in the art would easily realize it is not limited to this.

Please refer to FIG. 1, which is a schematic drawing illustrating a semiconductor fabricating apparatus in a first step of a cleansing process. In the cleansing process, the fourth valve 202 is closed, the third valve 302 is operated to close the second gas pipeline 20, the first valve 112 is opened, and the second valve 122 is closed, consequently the first cleansing gas HF is allowed to flow into the reaction chamber 30 through the first cleansing pipeline 110, the second connection pipeline 320, and the first connection pipeline 310 in the cleansing process. It is well-known that HF is a very toxic and corrosive material and therefore is widely used as an etching or cleansing agent in semiconductor industry. Consequently, the first cleansing gas HF is provided to remove any particles or contamination generated in a fabricating process that have been performed before and remained in the reaction chamber 30.

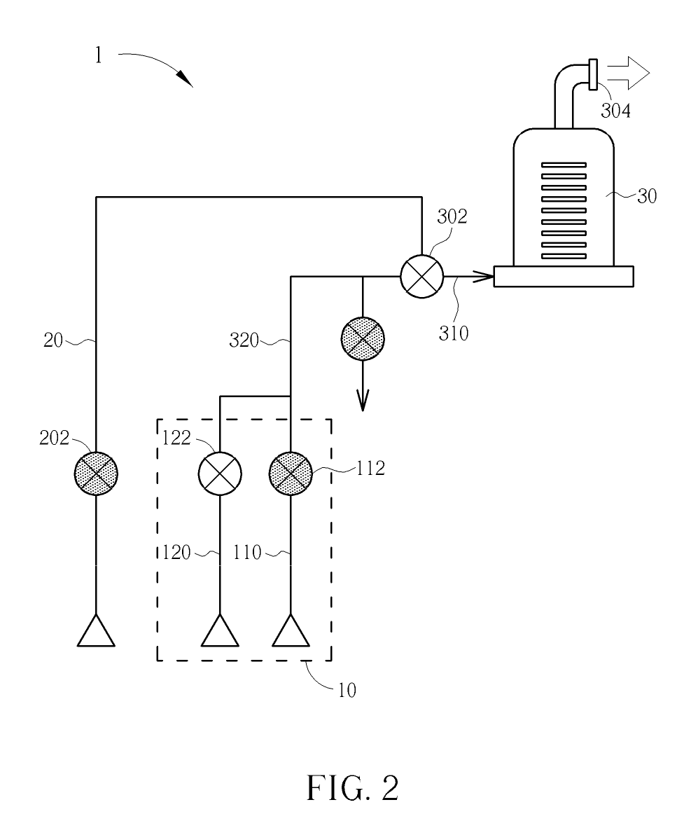

Please refer to FIG. 2, which is a schematic drawing illustrating a semiconductor fabricating apparatus in a second step of the cleansing process. After cleaning the reaction chamber 30 with the first cleansing gas HF, the third valve 302 and the fourth valve 202 are remained to close the second gas pipeline 20 while the first valve 112 is closed and the second valve 122 is opened, consequently, the second cleansing gas N₂ is allowed to flow into the reaction chamber 30 through the second cleansing gas pipeline 120, the second connection pipeline 320, and the first connection pipeline 310 in the cleansing process. As mentioned above, since HF is a very corrosive material, it corrodes and damages the first cleansing gas pipeline 110, the second connection pipeline 320 and the first connection pipeline 310 during the cleansing process. Consequently, particles or contaminations are generated and flowed into the reaction chamber 30 with the first cleansing gas HF. Therefore, the preferred embodiment provides the second cleansing gas N₂, which is non-reactive to the first cleansing gas HF, to drive out and purge the first cleansing gas HF and the contaminations from the second connection pipeline 320, the first connection pipeline 310 and, most important, the reaction chamber 30.

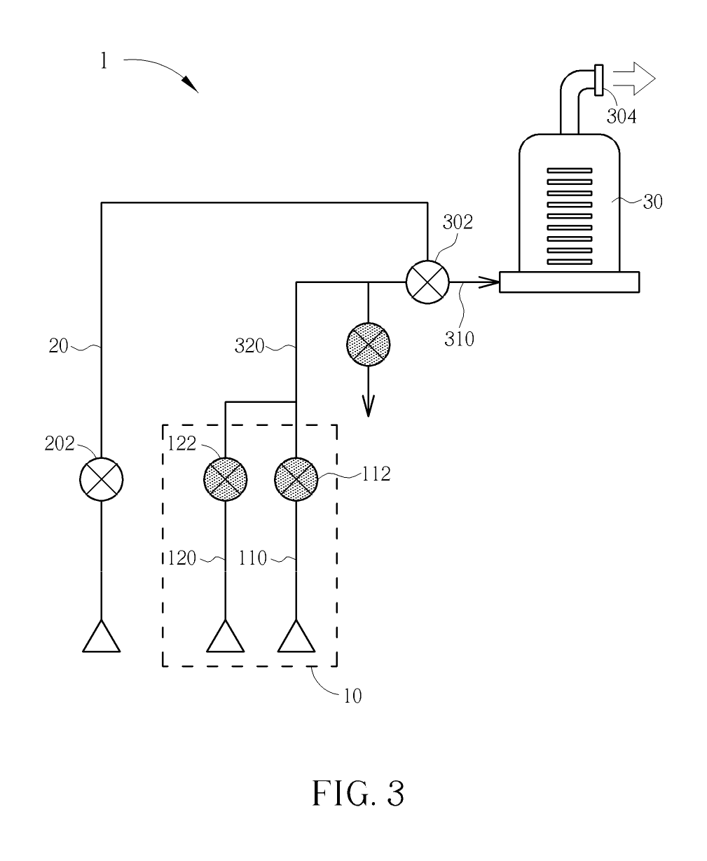

Please refer to FIG. 3, which is a schematic drawing illustrating a semiconductor fabricating apparatus in a fabricating process. In the fabricating process, the fourth valve 202 is opened, the third valve 302 is operated to close the first gas pipeline 10, and both of the first valve 112 and the second valve 122 are closed. Therefore, the reactive gas, which includes N₂ in the preferred embodiment, is allowed to flow into the reaction chamber 30 through the second gas pipeline 20 and the first connection pipeline 310 in the fabricating process. It is noteworthy that since the reactive gas and the second cleansing gas both include N₂, no reactions are to occur between the cleansing process and the fabricating process, and thus the safety, reliability, and yield of the fabricating process are all improved. It is also noteworthy that there are two valves closed (the first valve 112 is closed and the third valve 302 is operated to close the second connection pipeline 320) in the fabricating process function as a double insurance mechanism that any HF gas leakage will not flow into the reaction chamber 30. In other words, the safety, reliability, and yield of the fabricating process are ensured.

According to the semiconductor fabricating apparatus provided by the present invention, the first cleansing gas is introduced to clean the reaction chamber in the cleansing process. The first cleansing gas and any contamination generated in the cleansing process are driven out from the reaction chamber by the second cleansing gas. Consequently, superior cleanliness of the reaction chamber is ensured. After the cleansing process which involves both of the first cleansing gas and the second cleansing gas, the reactive gas is introduced into the reaction chamber through the second gas pipeline in the fabricating process. Since the contaminations and the remnant gas are all removed from the reaction chamber, there will be no adverse impact rendered to the semiconductor fabricating process performed in the reaction chamber. Additionally, since the reactive gas and the second cleansing gas include the same material, no reactions are to occur between the cleansing process and the fabricating process, and thus the safety, reliability, and yield of the fabricating process are all improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor fabricating apparatus comprising:
a reaction chamber;
a first gas pipeline comprising:
a first cleaning gas pipeline, providing a first cleansing gas to the reaction chamber in a cleansing process; and
a second cleansing gas pipeline, providing a second cleansing gas to the reaction chamber in the cleansing process, the first cleansing gas pipeline and the second cleansing gas pipeline being connected in parallel; and
a second gas pipeline for providing a reactive gas to the reaction chamber in a fabricating process, the first gas pipeline and the second gas pipeline being connected in parallel.

2. The semiconductor fabricating apparatus according to claim 1, further comprising a first connection pipeline connecting the first gas pipeline and the second gas pipeline to the reaction chamber.

3. The semiconductor fabricating apparatus according to claim 2, further comprising a second connection pipeline connecting the first cleansing gas pipeline and the second cleansing gas pipeline.

4. The semiconductor fabricating apparatus according to claim 3, further comprising a first valve positioned at the first cleansing gas pipeline, a second valve positioned at the second cleansing gas pipeline, and a third valve positioned at a joint between the first gas pipeline and the second gas pipeline, the third valve is a triple action valve.

5. The semiconductor fabricating apparatus according to claim 4, wherein the third valve is operated to close the second gas pipeline in the cleansing process.

6. The semiconductor fabricating apparatus according to claim 5, wherein the first valve is opened and the second valve is closed to allow the first cleansing gas flow into the reaction chamber through the first cleansing pipeline, the second connection pipeline, and the first connection pipeline in the cleansing process.

7. The semiconductor fabricating apparatus according to claim 6, wherein the first valve is closed and the second valve is opened to allow the second cleansing gas flow into the reaction chamber through the second cleansing pipeline, the second connection pipeline, and the first connection pipeline.

8. The semiconductor fabricating apparatus according to claim 7, wherein the second cleansing gas drives out the first cleansing gas from the action chamber.

9. The semiconductor fabricating apparatus according to claim 4, wherein the third valve is operated to close the first gas pipeline in the fabricating process and to allow the reactive gas flow into the action chamber through the second gas pipeline and the first connection pipeline.

10. The semiconductor fabricating apparatus according to claim 1, wherein the second cleansing gas is different from the first cleansing gas.

11. The semiconductor fabricating apparatus according to claim 10, wherein the first cleansing gas comprises HF and the second cleansing gas comprises N₂.

12. The semiconductor fabricating apparatus according to claim 1, wherein the second cleansing gas and the reactive gas comprise a same gas.

13. The semiconductor fabricating apparatus according to claim 12, wherein the second cleansing gas and the reactive gas comprise N₂.
